(19) United States
(12) Patent Application Publication
(10) Pub. No.: US 2008/0268210 A1
(43) Pub. Date: Oct. 30, 2008

(54) MANUFACTURING METHOD OF ELECTRONIC COMPONENT

(75) Inventor: Masahiro Sunohara, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 11/960,200

(22) Filed: Dec. 19, 2007

(30) Foreign Application Priority Data
Dec. 21, 2006 (JP) 2006-344690

(51) Int. Cl. B32B 5/00; G03F 7/20

(52) U.S. Cl. 428/195.1; 430/313

(57) ABSTRACT

A manufacturing method of an electronic component, characterized by having a first step of forming a treated substrate with a reinforcing part having a treated substrate body and a reinforcing part of the treated substrate body standing on a first principal surface of the treated substrate body, a second step of forming a first conductive pattern on the side of the first principal surface of the treated substrate body and forming a second conductive pattern on the side of a second principal surface of the treated substrate body, respectively, and a third step of cutting the treated substrate body and eliminating the reinforcing part and also dividing the treated substrate body into individual pieces.

### TECHNICAL FIELD

The present invention relates to a manufacturing method of an electronic component made by forming a conductive pattern on both surfaces of a substrate.

### BACKGROUND ART

For example, with a substrate on which an element is mounted, various structures have been proposed, and demands for high integration and thinning of the substrate are increasing with high integration and miniaturization of recent electronic apparatus. As a result of this, there are cases where a conductive pattern (wiring pattern) is formed on both surfaces of a substrate and also an electronic component (interposer) having a structure in which the substrate is thinned is used.

For example, in the case of manufacturing an electronic component having a structure in which a conductive pattern is formed on both surfaces of the substrate, it is necessary to make the substrate thin before at least the conductive pattern is formed. As a result of this, there were cases where problems that when the thinned substrate is processed, the substrate is broken and a yield of manufacture of the electronic component reduces arise.

Therefore, a method for bonding a support plate for supporting a substrate to a back surface of the substrate and processing the substrate has been proposed in order to prevent breakage of the thinned substrate (for example, see Japanese Patent Unexamined Publication JP-A-2004-221240).

However, when bonding the support plate to the substrate and processing the substrate, there are various factors in increasing manufacturing cost in bonding the support plate to the substrate and peeling of the support plate from the substrate. For example, in the case of bonding the support plate to the substrate, a resin adhesive is generally used.

However, steps of processing the substrate include, for example, a wet step (a step in which the substrate is immersed in a plating solution etc.) or a step exposed to high temperature, and a resin adhesive withstanding a variety of these steps is not substantially developed yet.

Because of this, a step of bonding again after the support plate is once peeled was required in order to replace an adhesive according to various loads in the steps of processing the substrate. As a result of this, there were fears that a manufacturing step of the electronic component becomes complicated and a manufacturing cost increases. In addition, the risk of breakage of the substrate in the case of peeling the support plate increases and a manufacturing cost increases from the standpoint of reduction in a yield.

### SUMMARY OF THE INVENTION

In view of the above, the overall problem of the invention is to provide a new and useful manufacturing method of the electronic component for solving the problems described above.

A concrete problem of the invention is to simplify a manufacturing method of the electronic component made by forming a conductive pattern on both surfaces of a substrate and reduce a manufacturing cost.

According to an aspect of the invention, there is provided a manufacturing method of an electronic component, including:

forming a treated substrate with a reinforcing part including:
a treated substrate body; and
a reinforcing part standing on a first principal surface of the treated substrate body;

forming a conductive pattern on the treated substrate body; and

cutting the treated substrate body so as to eliminate the reinforcing part and also divide the treated substrate body into individual pieces.

According to the invention, a manufacturing method of the electronic component made by forming the conductive pattern on both surfaces of a substrate can be simplified to reduce a manufacturing cost.

### BRIEF DESCRIPTION OF THE DRAWINGS

FIG. 1 is a diagram showing a configuration of an electronic component according to a first embodiment;

FIG. 2A is a first diagram showing a manufacturing method of the electronic component according to the first embodiment;

FIG. 2B is a second diagram showing a manufacturing method of the electronic component according to the first embodiment;

FIG. 2C is a third diagram showing a manufacturing method of the electronic component according to the first embodiment;

FIG. 2D is a fourth diagram showing a manufacturing method of the electronic component according to the first embodiment;

FIG. 2E is a fifth diagram showing a manufacturing method of the electronic component according to the first embodiment;

FIG. 2F is a sixth diagram showing a manufacturing method of the electronic component according to the first embodiment;

FIG. 2G is a seventh diagram showing a manufacturing method of the electronic component according to the first embodiment;

FIG. 2H is an eighth diagram showing a manufacturing method of the electronic component according to the first embodiment;

FIG. 2I is a ninth diagram showing a manufacturing method of the electronic component according to the first embodiment;

FIG. 2J is a tenth diagram showing a manufacturing method of the electronic component according to the first embodiment;

FIG. 2K is an eleventh diagram showing a manufacturing method of the electronic component according to the first embodiment;

FIG. 2L is a twelfth diagram showing a manufacturing method of the electronic component according to the first embodiment;

FIG. 2M is a thirteenth diagram showing a manufacturing method of the electronic component according to the first embodiment;

FIG. 2N is a fourteenth diagram showing a manufacturing method of the electronic component according to the first embodiment;

FIG. 3A is a first diagram showing a manufacturing method of an electronic component according to a second embodiment;

FIG. 3B is a second diagram showing a manufacturing method of the electronic component according to the second embodiment;

FIG. 4A is a first diagram showing a manufacturing method of an electronic component according to a third embodiment;

FIG. 4B is a second diagram showing a manufacturing method of the electronic component according to the third embodiment;

FIG. 5 is a first diagram showing a modified example of the manufacturing method of the electronic component according to the first embodiment;

FIG. 6 is a second diagram showing a modified example of the manufacturing method of the electronic component according to the first embodiment;

FIG. 7 is a third diagram showing a modified example of the manufacturing method of the electronic component according to the first embodiment;

FIG. 8 is a fourth diagram showing a modified example of the manufacturing method of the electronic component according to the first embodiment; and

FIG. 9 is a fifth diagram showing a modified example of the manufacturing method of the electronic component according to the first embodiment;

FIG. 10 is a diagram showing an example of the substrate of the electronic component manufactured by using wet-etching; and

FIG. 11 is a diagram showing an example of the electronic component manufactured by using wet-etching.

### DETAILED DESCRIPTION OF THE PREFERRED EMBODIMENTS

A manufacturing method of an electronic component according to the invention has steps of

forming a treated substrate with a reinforcing part having a treated substrate body and a reinforcing part standing on a first principal surface of the treated substrate body,

forming a first conductive pattern on the first principal surface of the treated substrate body and

forming a second conductive pattern on a second principal surface of the treated substrate body, and

cutting the treated substrate body to eliminate the reinforcing part and divide the treated substrate body into individual pieces.

As a result of this, breakage of the thinned treated substrate body is suppressed by the reinforcing part. Also, the reinforcing part is eliminated while the treated substrate body is cut and is divided into individual pieces. As a result of this, in the manufacturing method, elimination of the reinforcing part is facilitated and also an increase in the risk of breakage of the treated substrate body by the elimination of the reinforcing part is suppressed.

Next, one example of a configuration of an electronic component manufactured by the manufacturing method and an example of the manufacturing method of the electronic component will hereinafter be described by using the drawings.

### First Embodiment

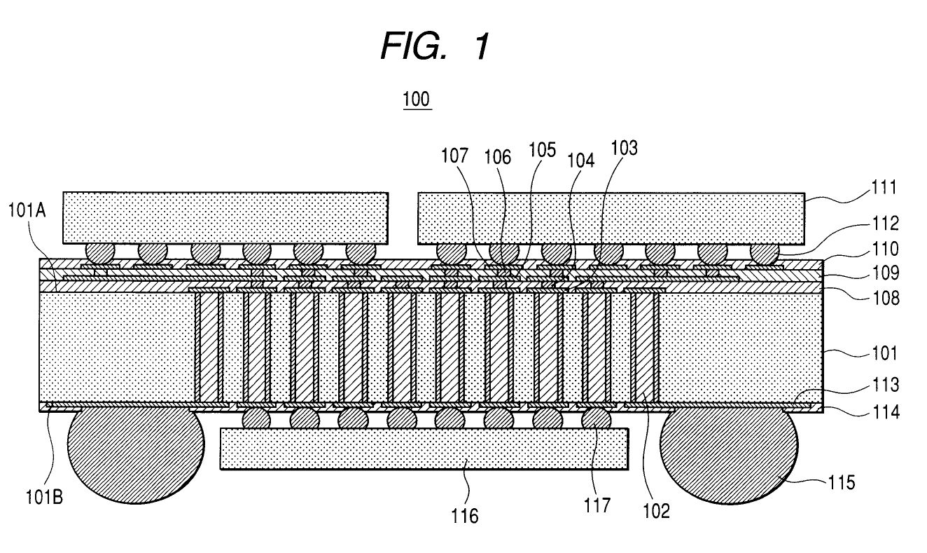

FIG. 1 is a sectional diagram schematically showing an electronic component according to a first embodiment of the invention. Referring to FIG. 1, an electronic component 100 according to the present embodiment is configured to have

a substrate (substrate body) 101 made of a semiconductor material such as silicon,

conductive patterns 103 to 107 formed on a first principal surface 101A of the substrate 101, and

a conductive pattern 113 formed on a second principal surface 101B opposite to the first principal surface 101A of the substrate 101.

Also, the conductive patterns of the first principal surface 101A are constructed so as to be electrically connected to the conductive pattern of the second principal surface 101B by a via-plug 102 extending through the substrate 101.

First, referring to the first principal surface 101A, the conductive pattern 103 formed on the first principal surface 101A is made of pattern wiring connected to the via-plug 102. Also, an insulating layer 108 made of, for example, an epoxy based resin material is formed so as to cover the via-plug 102. The conductive pattern 104 including a via-plug connected to the conductive pattern 103 while extending through the insulating layer 108 is formed.

Further, the conductive pattern 105 made of pattern wiring connected to the conductive pattern 104 is formed on the insulating layer 108. An insulating layer 109 made of, for example, an epoxy based resin material is laminated on the insulating layer 108 so as to cover the conductive pattern 105.

Also, the conductive pattern 106 including a via-plug connected to the conductive pattern 105 while extending through the insulating layer 109 is formed. Further, the conductive pattern 107 made of pattern wiring connected to the conductive pattern 106 is formed on the insulating layer 109.

Also, a solder resist layer (insulating layer) 110 is formed so as to cover a part of the conductive pattern 107 and the insulating layer 109.

Also, the conductive pattern 113 formed on the second principal surface 101B is made of pattern wiring connected to the via-plug 102, and a solder resist layer (insulating layer) 114 is formed so as to cover a part of the second principal surface 101B and the conductive pattern 113.

Also, on the first principal surface 101A or the second principal surface 101B of the electronic component described above, for example, a semiconductor chip may be mounted and also, for example, an external connection terminal such as a bump may be formed.

For example, plural semiconductor chips 111 are mounted on the first principal surface 101A. In this case, the semiconductor chips 111 are mounted (mounted by flip-chip bonding) so as to be connected to the conductive pattern 107 by bumps 112.

Similarly, a semiconductor chip 116 is mounted on the second principal surface 101B. In this case, the semiconductor chip 116 is mounted (mounted by flip chip bonding) so as to be connected to the conductive pattern 113 by bumps 117.

Further, external connection terminals (bumps) 115 are installed on the second principal surface 101B so as to be connected to the conductive pattern 113, and it is constructed so as to become easy to mount the electronic component 100 on a substrate such as a motherboard.

The electronic component 100 described above is constructed so that the conductive patterns are formed on both surfaces (both the first principal surface 101A and the second principal surface 110B) of the substrate 101 and these conductive patterns are electrically connected by the via-plug 102 extending through the substrate 101. As a result of this, in the case of manufacturing the electronic component 100, it is substantially difficult to thin the substrate 101 by back grinding after the conductive pattern or the via-plug is formed in the substrate 101. Therefore, in the case of manufacturing the electronic component having the construction described above, it is necessary to perform processing for forming the conductive pattern or the via-plug with respect to the substrate thinned previously (thinned to the extent of a thickness of the substrate 101 formed finally).

For example, a thickness of the substrate 101 (interposer) made of silicon described above is about 50 μm to 200 μm, and is generally made thinner than 600 μm to 800 μm which is a thickness of a silicon wafer.

As a result of this, in a manufacturing method of the electronic component according to the embodiment, breakage of a substrate in manufacture of the electronic component is suppressed by using a substrate having a reinforcing part. Also, an effect of facilitating transport of the substrate is obtained by forming the reinforcing part.

Next, one example of the manufacturing method of the electronic component mentioned above will be described. However, in the following diagrams, the same numerals are assigned to the portions described above and the description may be omitted (similar matters apply to the following embodiments).

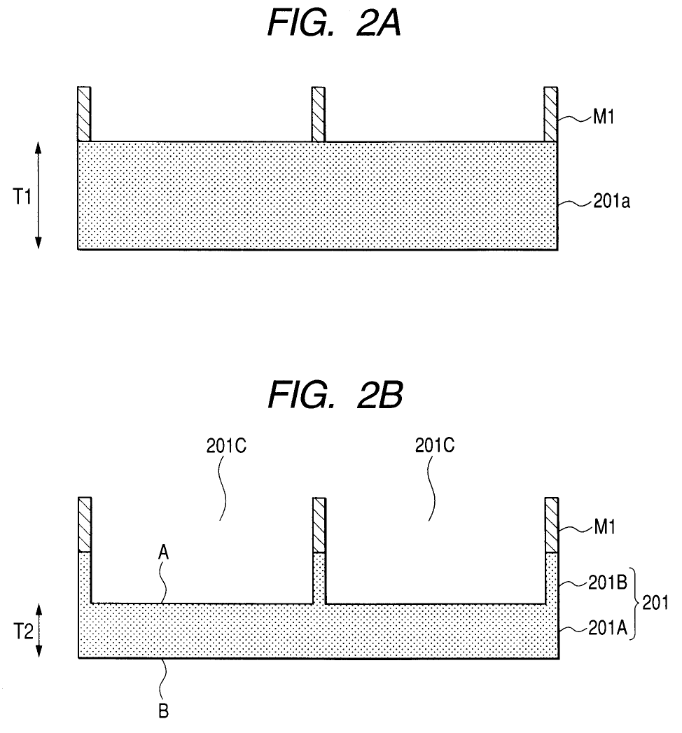

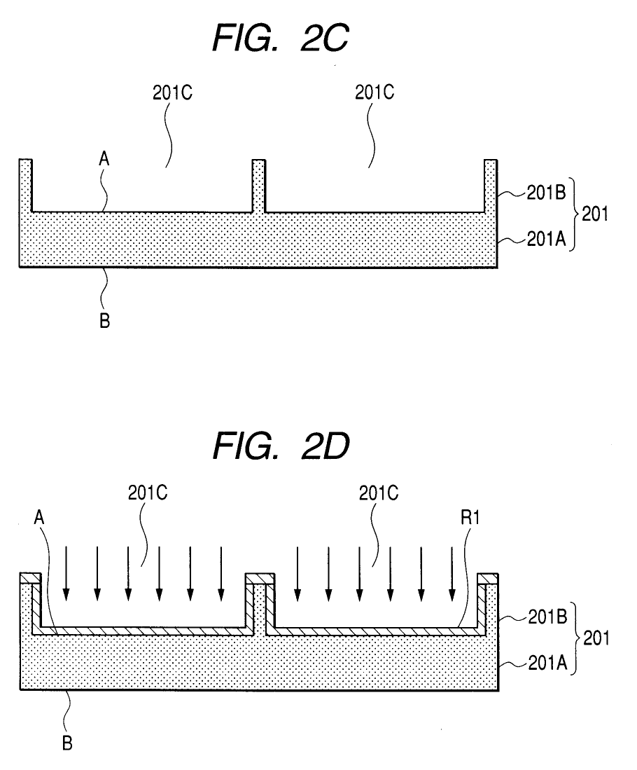

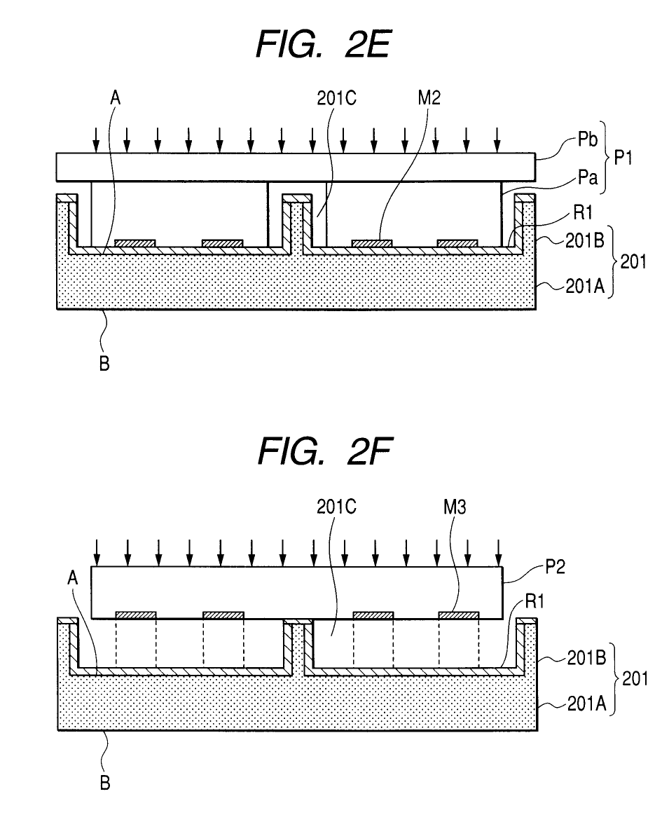

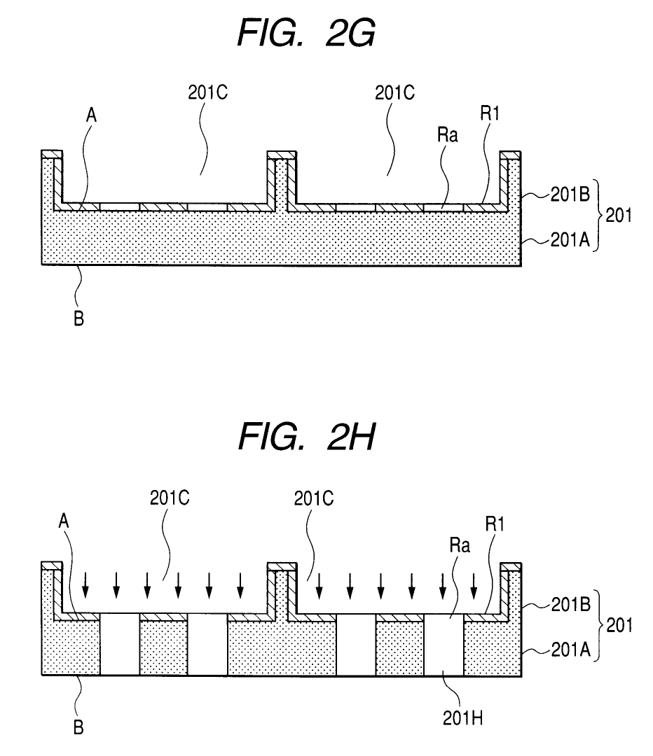

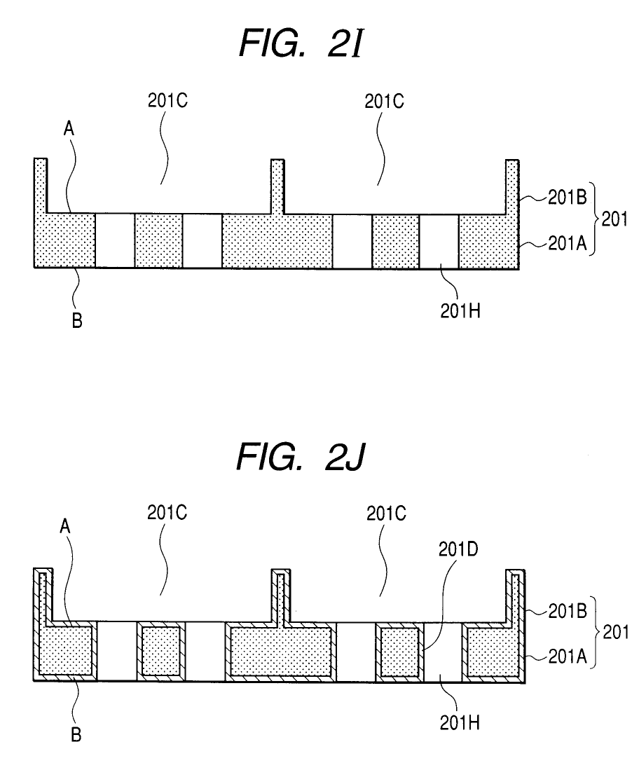

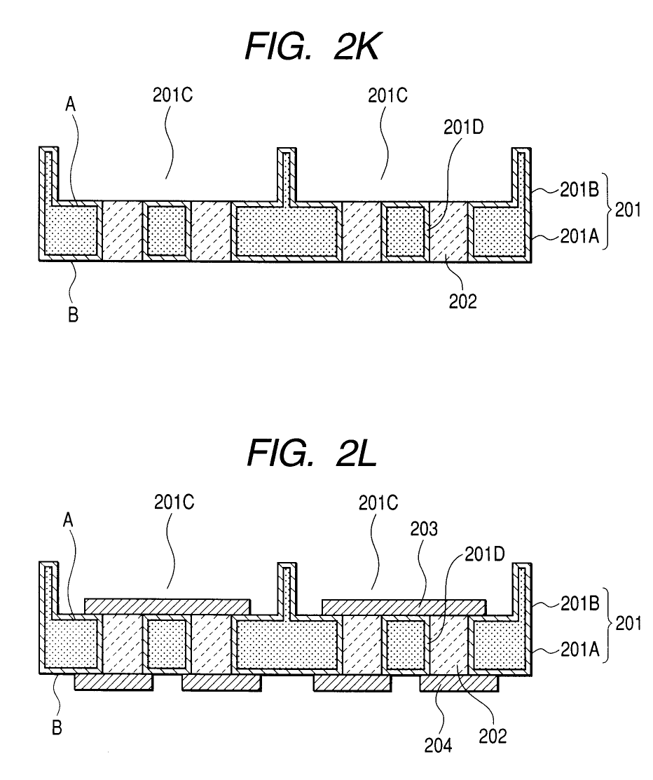

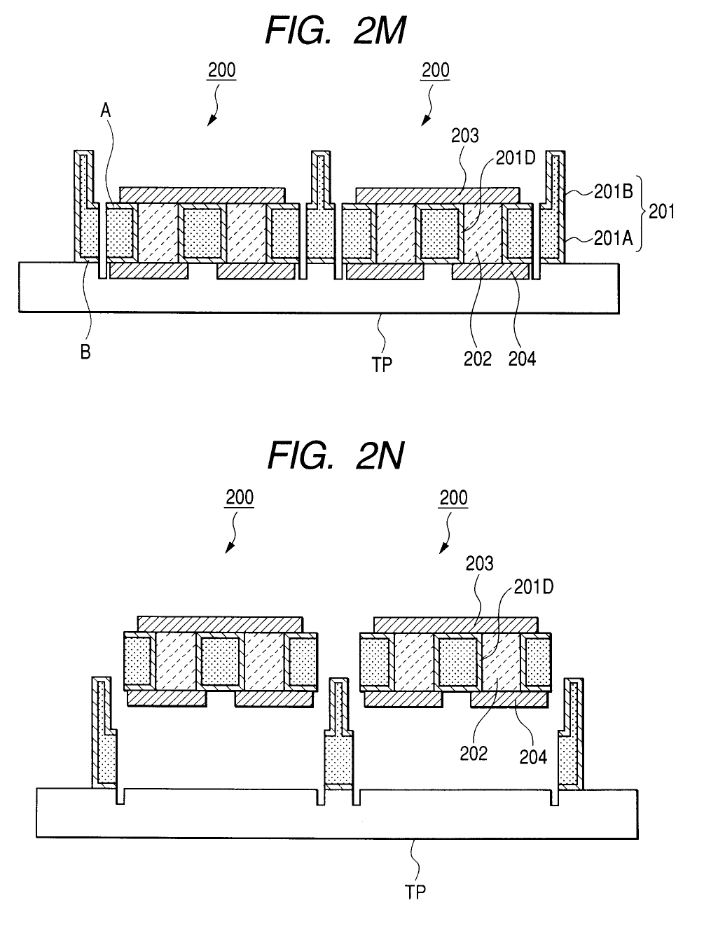

First, in a step shown in FIG. 2A, a resist layer is formed on a treated substrate 201a made of a silicon wafer whose thickness T1 is, for example, about 600 μm to 800 μm. A mask pattern M1 is formed by patterning the resist layer by a photolithography method. The resist layer can be formed by application of a liquid resist or pasting of a resist on a film.

Next, in a step shown in FIG. 2B, by etching process by using the mask pattern M1 as a mask, the treated substrate 201a is etched and plural recessed parts 201C are formed. As a result of this, a treated substrate 201 with a reinforcing part having a treated substrate body 201A processed thinner than the treated substrate 201a and a rib-shaped reinforcing part 201B standing on a first principal surface A of the treated substrate body 201A is formed. For example, a thickness T2 of the treated substrate body 201A is set at about 50 μm to 200 μm. Also, a second principal surface B opposite to the first principal surface A of the treated substrate body 201A is maintained in a flat state.

Also, any of wet etching or dry etching using plasma may be used as the etching. Also, a method by mechanical etching (grinding, polishing, etc.) as described below may be used.

Then, in a step shown in FIG. 2C, the mask pattern M1 is peeled.

Then, in a step shown in FIG. 2D, a resist layer R1 is formed on inner wall surfaces of the recessed parts 201C by pushing and pressurizing a resist layer made of, for example, a film resin material (dry film resist) to the recessed parts 201C. In this case, the stress of pushing the resist layer R1 is set at about 0.1 to 1.0 MPa and the temperature is set at about 70 to 130° C.

Then, in a step shown in FIG. 2E, the resist layer R1 is exposed by using an optical mask M2 and patterning is performed.

In this case, the rib-shaped reinforcing part 201B is formed in the treated substrate body 201A, so that it is preferable to use a jig P1 shown in FIG. 2E in order to bring the optical mask M2 into contact with the resist layer R1.

The jig P1 is optically transparent and has a structure made by forming plural protrusion parts Pa on a flat-plate shaped base plate Pb. The plural protrusion parts Pa have a shape corresponding to the recessed parts 201C (reinforcing part 201B). That is, the protrusion parts Pa are formed in a shape inserted into the recessed parts 201C defined by the treated substrate body 201A and the reinforcing part 201B. The optical mask M2 is provided in the side facing the treated substrate body 201A (first principal surface) of the protrusion parts Pa.

In FIG. 2E, the optical mask M2 is illustrated to be embedded in the protrusion part Pa, FIG. 2E is illustrated so as to emphasize that a lower face of the protrusion part including the mask M2 is flat to closely contact with the recessed part 201C. However, because the mask M2 is very thin and the thickness of the mask M2 is neglectable, actually, the mask M2 is formed on a flat bottom face of the protrusion part Pa.

As a result of this, the optical mask M2 is installed so as to make substantial contact with the resist layer R1, and the so-called contact exposure can be performed. As a result of this, the resist layer R1 can be patterned with high accuracy.

Also, the exposure described above may be performed by projection exposure as shown in FIG. 2F. For example, in the case shown in FIG. 2F, an opaque film M3 is formed in a side facing the treated substrate body 201A (first principal surface) of a transparent substrate P2 to form a flat-plate shaped mask. In this case, the projection exposure can be performed by making adjustment so that a focal point of exposure matches with the resist layer R1.

Then, in a step shown in FIG. 2G, the resist layer of the portion which is not exposed is removed by development and openings Ra are formed in the resist layer R1. The openings Ra correspond to positions of via-plugs formed in the treated substrate body 201A in a subsequent step.

Then, in a step shown in FIG. 2H, via-holes 201H extending through the treated substrate body 201A are formed by etching using the resist layer R1 as a mask. Any of wet etching or dry etching using plasma may be used as the etching.

Then, in a step shown in FIG. 2I, the resist layer R1 is peeled.

Then, in a step shown in FIG. 2J, an insulating film (silicon oxide film) 201D is formed on a surface of the treated substrate 201 with the reinforcing part made of silicon by, for example, thermal oxidation. For example, the insulating film 201D is formed on both of the reinforcing part 201B and the surface of the treated substrate body 201A and is also formed on inner wall surfaces of the via-holes 201H.

By forming the insulating film 201D, the treated substrate body 201A made of silicon is insulated from a conductive pattern or a via-plug formed in a subsequent step. The insulating film 201D is formed so that, for example, the thickness becomes about 1 μm.

Then, in a step shown in FIG. 2K, via-plugs 202 for burying the via-holes 201H formed in the treated substrate body 201A are formed by a known method. For example, the via-plugs 202 can be formed by a Cu plating method.

For example, after a seed layer is formed by electroless plating etc., the portion which is not desired to be plated is protected by a resist layer (mask pattern) and the via-plugs 202 can be formed by electrolytic plating. Also, the seed layer can be formed by, for example, pasting a layer made of Cu so as to close the bottoms of the via-holes 201H rather than the electroless plating. In this case, by electrolytic plating, Cu grows from the bottoms of the via-holes.

Then, in a step shown in FIG. 2L, a conductive pattern (pattern wiring) 203 electrically connected to the via-plugs 202 is formed on the first principal surface A of the treated substrate body 201A by a known semi-additive method. Similarly, a conductive pattern (pattern wiring) 204 electrically connected to the via-plugs 202 is formed on the second principal surface B of the treated substrate body 201A by the known semi-additive method.

In the semi-additive method, a seed layer is first formed by electroless plating or a sputtering method, etc. Then, a resist layer is formed on the seed layer and the resist layer is patterned by a photolithography method whereby a mask pattern is formed. Next, a conductive pattern is formed by an electrolytic plating method using the mask pattern as a mask. Also, after the conductive pattern is formed, the mask pattern (resist) is removed and the seed layer exposed by removal of the mask pattern is removed by etching. By performing these steps, the conductive patterns 203, 204 can be formed.

Then, in a step shown in FIG. 2M, the treated substrate 201 with the reinforcing part (treated substrate body 201A) is pasted on tape (dicing tape) TP made of a resin material and the treated substrate body 201A is cut by a dicing blade (dicing).

By the dicing, the treated substrate body 201A is divided into individual pieces and also the reinforcing part 201B is eliminated (separated) from each of the treated substrate bodies 201A divided into individual pieces. Here, the conductive pattern 203 is formed on the first principal surface A of the treated substrate body 201A and the conductive pattern 204 is formed on the second principal surface B. Plural electronic components (interposers) 200 made by electrically connecting the conductive pattern 203 to the conductive pattern 204 by the via-plugs 202 extending through the treated substrate body 201A are formed.

Then, in a step shown in FIG. 2N, the electronic components 200 are picked up and are peeled from the tape TP.

That is, in the manufacturing method described above, the plural electronic components 200 are cut out of one treated substrate 201 with the reinforcing part.

Also, the treated substrate body 201A, the via-plug 202, the conductive pattern 203 and the conductive pattern 204 of the electronic component 200 respectively correspond to the substrate 100, the via-plug 102, the conductive patterns 103 to 107 and the conductive pattern 113 of the electronic component 100 shown in FIG. 1. That is, the electronic component 100 shown in FIG. 1 can be manufactured by the manufacturing method described above.

Also, a multilayer wiring structure as shown in FIG. 1 may be formed by further laminating a conductive pattern or an insulating layer on the first principal surface A of the electronic component 200 by a known method. Also, the multilayer wiring structure may be formed on the second principal surface B. Also, a semiconductor chip may be mounted on the first principal surface A or the second principal surface B. Also, an external connection terminal (bump) may be disposed on the first principal surface A or the second principal surface B.

The manufacturing method of the electronic component according to the embodiment described above is that the rib-shaped reinforcing part 201B connected to the treated substrate body 201A is installed so as to stand on the first principal surface A of the treated substrate body 201A until just before cutting of the treated substrate body 201A by dicing (from the step of FIG. 2B to the step of FIG. 2L).

As a result of this, effects in which strength of the treated substrate 201 can be maintained and breakage of the treated substrate body 201A is suppressed in the case of performing processing for forming a via-plug or a conductive pattern in the treated substrate body 201A are obtained. Also, an effect of facilitating transport of the treated substrate body 201A (treated substrate 201 with the reinforcing part) is obtained.

In a conventional manufacturing method of an electronic component, there were cases of adopting a method for pasting a support plate (reinforcing plate) for supporting (reinforcing) a treated substrate to the treated substrate (treated substrate body). However, it is difficult for a resin adhesive used in the case of pasting the support plate to the substrate to withstand all the step exposed to high temperature or the wet step (step immersed in a plating solution or an etching solution) in steps of processing the substrate. Because of this, it was necessary to again paste after the support plate is once peeled in order to replace an adhesive according to loads in the various steps of processing the substrate. As a result of this, the conventional method had fears that a manufacturing step of the electronic component becomes complicated and a manufacturing cost increases. In addition, the risk of breakage of the substrate in the case of peeling the support plate increases and a manufacturing cost increases from the standpoint of reduction in a yield.

On the other hand, in the method according to the embodiment, the reinforcing part 201B is separated and eliminated from each of the treated substrate bodies 201A divided into individual pieces in a state of being connected to the treated substrate body 201A. As a result of this, the manufacturing method according to the embodiment does not require a step of peeling a support plate as described in the conventional method and has no fear of an increase in the risk of breakage of the substrate in the step of peeling the support plate.

Also, since the reinforcing part 201B is eliminated (separated) at the same time of dividing the treated substrate body 201A into individual pieces by dicing, a step does not increase substantially in order to eliminate the reinforcing part 201B. That is, in the manufacturing method according to the embodiment, the reinforcing part 201B can be eliminated (separated) by performing a step substantially similar to a conventional dicing step (step of being divided into individual pieces).

Therefore, according to the manufacturing method of the electronic component according to the embodiment, a manufacturing step is simple and a manufacturing cost is reduced and also a yield of manufacture is good.

Also, a method for forming the treated substrate with the reinforcing part is not limited to the method shown in FIGS. 2A to 2C of the embodiment, and can be performed by various methods as shown in, for example, the following second embodiment and third embodiment.

### Second Embodiment

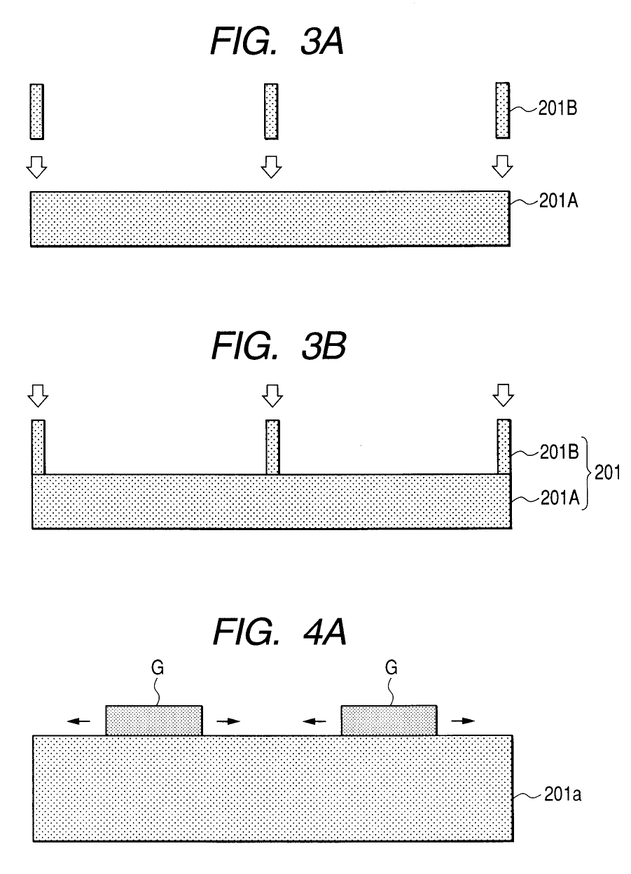

FIGS. 3A and 3B correspond to the step shown in FIGS. 2A to 2C of the first embodiment, and show another method for forming a treated substrate with a reinforcing part.

In the case shown in the present embodiment, a treated substrate 201 with a reinforcing part is formed by joining a rib-shaped reinforcing part 201B on a treated substrate body 201A previously thinned (to a thickness of, for example, about 50 μm to 200 μm).

For example, when both the treated substrate body 201A and the reinforcing part 201B are made of silicon, by pushing and pressurizing the reinforcing part 201B on the treated substrate body 201A and further heating at about 1000° C., the treated substrate body 201A and the reinforcing part 201B can be joined by direct joining of silicon.

Also, in a case where the treated substrate body 201A is made of silicon and the reinforcing part 201B is made of glass, or a case where the treated substrate body 201A is made of glass and the reinforcing part 201B is made of silicon, the treated substrate body 201A and the reinforcing part 201B can be joined by anode joining.

Also, even when both the treated substrate body 201A and the reinforcing part 201B are made of silicon, anode joining can be performed by forming a layer made of SiO₂ (glass) on any of the treated substrate body 201A and the reinforcing part 201B by, for example, sputtering or application.

Also, regardless of material of the treated substrate body 201A and the reinforcing part 201B, for example, by forming layers for joining made of Au, solder or glass etc. on both the treated substrate body 201A and the reinforcing part 201B, the treated substrate body 201A and the reinforcing part 201B can be joined by ultrasonic joining or joining by pressurization and heating.

### Third Embodiment

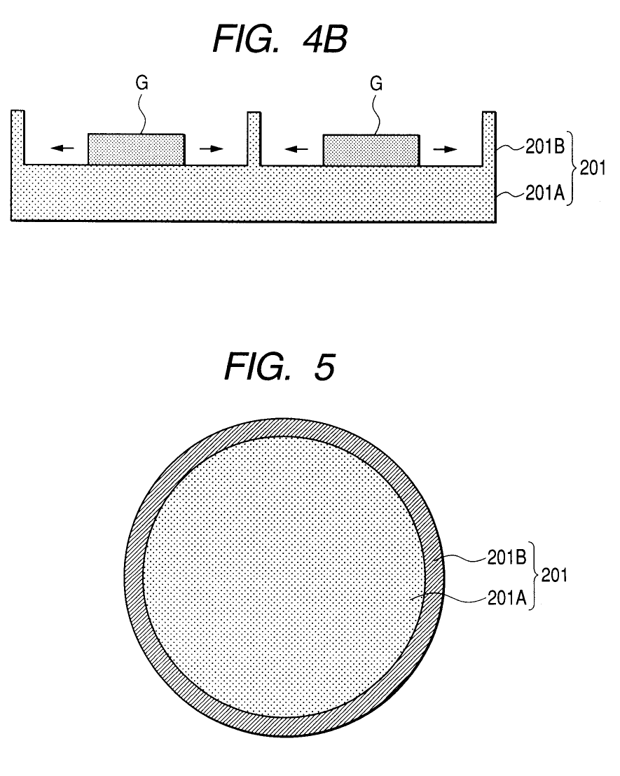

Also, FIGS. 4A and 4B correspond to the step shown in FIGS. 2A to 2C of the first embodiment, and show a further other method for forming a treated substrate with a reinforcing part.

In the case of the present embodiment, a treated substrate 201 with a reinforcing part is formed by processing a treated substrate 201a using a method by mechanical etching (grinding, polishing, etc.).

For example, by etching (grinding, polishing) the treated substrate using grinding means (polishing means) G such as a grindstone, the treated substrate 201 with the reinforcing part made so that a reinforcing part 201B stands on a treated substrate body 201A can be formed in a manner similar to the case of the first embodiment.

Also, a structure, an operation, etc. of the grinding means G may be changed properly by a structure of the reinforcing part 201B.

### Fourth Embodiment

Also, structure and construction of a reinforcing part 201B may be modified and changed variously. Examples of construction of the reinforcing part 201B are shown below.

FIGS. 5 to 9 are plan diagrams schematically showing the construction of the reinforcing part 201B formed (joined) on a treated substrate body 201A. Also, FIGS. 5 to 9 assume that the treated substrate body 201A is formed using a silicon wafer.

Referring first to FIG. 5, a reinforcing part 201B is formed in a circle shape at the peripheral edge of a treated substrate body 201A in the case shown in the present diagram. Generally, a product (a region used as an interposer finally) is not formed at the peripheral edge of a wafer. As a result of this, the number of electronic components produced from one wafer can be increased even when the reinforcing part is formed in a structure shown in the present diagram.

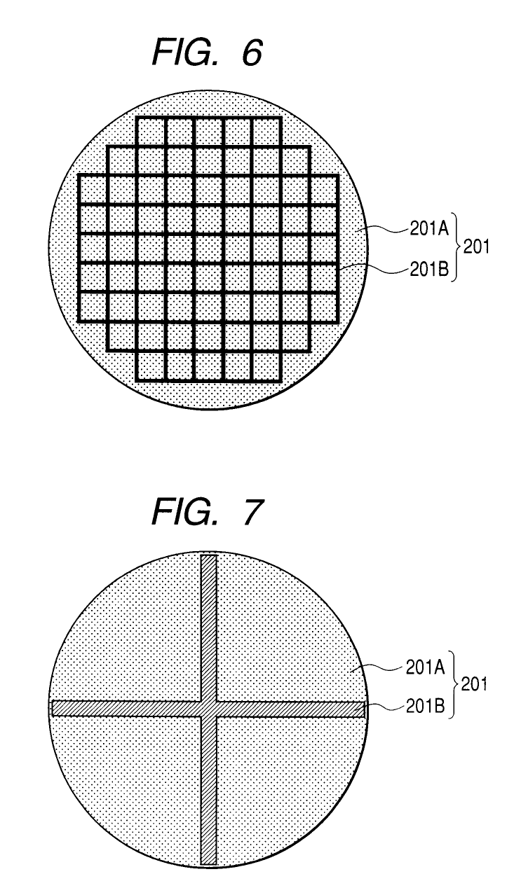

Also, referring to FIG. 6, a reinforcing part 201B is formed in a lattice shape in the case shown in the present diagram. Also, it is preferable to form the reinforcing part 201B in correspondence with a scribe line of a treated substrate body 201A. Since a product is not formed in the scribe line, the number of electronic components produced from one wafer can be increased even when the reinforcing part is formed in a structure shown in the present diagram.

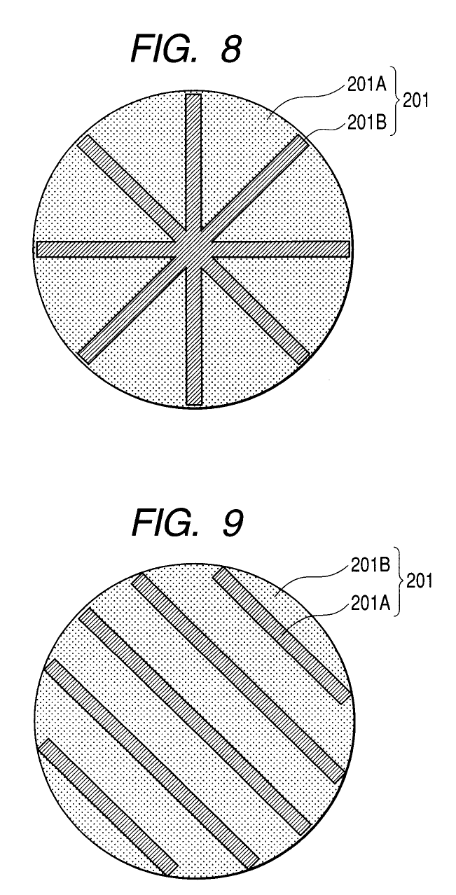

Also, a reinforcing part 201B may be constructed by a rib formed in plural straight shapes (stripe shapes) as shown in FIGS. 7 to 9. In this case, for example, the reinforcing part may be constructed so that stripe-shaped ribs intersect at the center of a wafer (FIGS. 7 and 8). Also, the intersecting ribs may be two ribs (FIG. 7) or may be plural (two or more) ribs (FIG. 8).

Also, the stripe-shaped ribs may be formed diagonally with respect to a crystal direction of a wafer as shown in FIG. 9.

Although the above described embodiments direct to an electronic component in which the conductive patterns are formed on both surface of the substrate, the present invention does not limit thereto. The present invention can apply to manufacture an electronic component in which a conductive pattern is formed on only one side of the substrate.

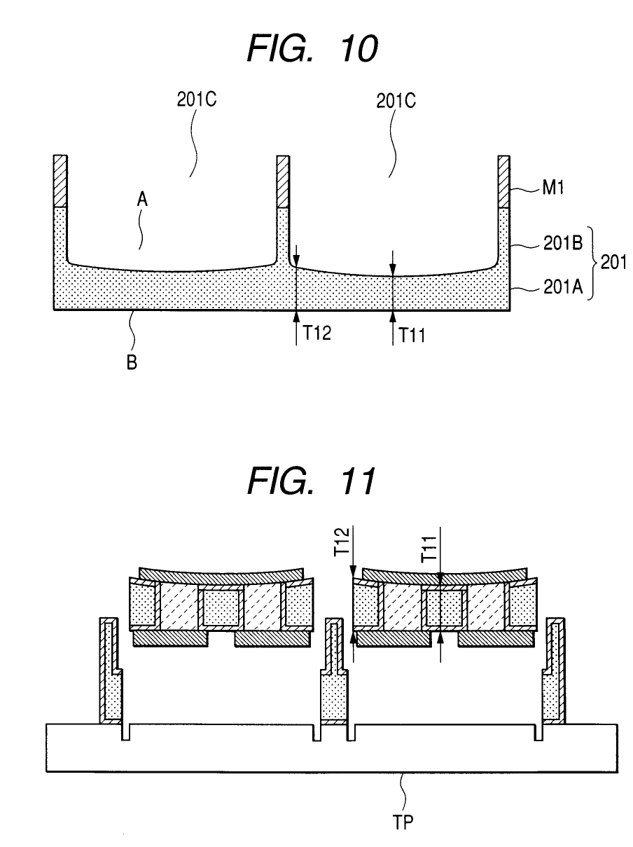

Next, an example of an electronic component manufactured by the present invention is described by using FIGS. 10 and 11.

By using wet-etching to form the recessed part 201C, due to the variation in etching rate on the processing surface of the substrate 201A, a central portion is deeply etched relative to edge portion of the substrate 201A. Therefore, by using the wet etching to form the resist film, thickness T11 at a central portion of the obtained substrate is smaller than thickness T12 of an edge portion of the same, as shown in FIG. 10.

Accordingly, in a case where a lattice-shaped reinforcing part 201C as shown in FIG. 6, which is obtained by a lattice-shaped resist film, is used and individual electronic component is obtained by one area partitioned by the lattice reinforcing part, thickness T11 of the central portion of the obtained substrate is smaller than thickness T12 of the edge portion of the obtained substrate.

Of course, other than the above described electronic components having curved a surface, when using dry etching at the time of forming the recessed part 201, the above described variation in etching rate hardly occurs and an electronic component with flat surface is obtained.

The invention has been described above with reference to the preferred embodiments, but the invention is not limited to the specific embodiments described above, and various modifications and changes can be made within the gist described in the claims.

For example, in the embodiments described above, the case of making the treated substrate (treated substrate body) of silicon has been described as an example, but the invention is not limited to this case. For example, even when the treated substrate (treated substrate body) is made of glass, ceramic or resin material, an electronic component can be manufactured in a manner similar to the embodiments described above.

According to the invention, a manufacturing method of an electronic component made by forming a conductive pattern on both surfaces of a substrate can be simplified to reduce a manufacturing cost.

What is claimed is:

1. A manufacturing method of an electronic component, comprising:
forming a treated substrate with a reinforcing part comprising:
a treated substrate body; and
a reinforcing part standing on a first principal surface of the treated substrate body;
forming a conductive pattern on the treated substrate body; and
cutting the treated substrate body so as to eliminate the reinforcing part and also divide the treated substrate body into individual pieces.

2. The manufacturing method of the electronic component as set forth in claim 1, wherein
the reinforcing part is formed in a circle shape at a peripheral edge of the treated substrate body.

3. The manufacturing method of the electronic component as set forth in claim 1, wherein
the reinforcing part is formed in a lattice shape in a plane view.

4. The manufacturing method of the electronic component as set forth in claim 1, wherein
the reinforcing part is formed in correspondence with a scribe line which is appears when the treated substrate body is divided into individual pieces.

5. The manufacturing method of the electronic component as set forth in claim 1, wherein
the treated substrate with the reinforcing part is formed by performing pattern etching of the treated substrate.

6. The manufacturing method of the electronic component as set forth in claim 1, wherein
the treated substrate with the reinforcing part is formed by joining the reinforcing part to the treated substrate body.

7. The manufacturing method of an electronic component as in set forth in claim 1, further comprising
forming a via-plug extending through the treated substrate,
wherein the first and the second conductive patterns are electrically connected through the via-plug.

8. The manufacturing method of the electronic component as set forth in claim 7, wherein
the step of forming the via-plug comprises:
forming a resist layer on the first principal surface;
patterning the resist layer by using an optical mask; and
etching the treated substrate body by using the patterned resist layer as a mask, and
wherein the optical mask is installed on a transparent jig, which comprises a protrusion part corresponding to the reinforcing part, at a side facing the first principal surface.

9. The manufacturing method of the electronic component as set forth in claim 1, wherein
the treated substrate body and the reinforcing part are made of silicon.

10. The manufacturing method of the electronic component as set forth in claim 1, wherein
when forming a conductive pattern on the treated substrate body, a first conductive layer is formed on the first principal surface.

11. The manufacturing method of the electronic component as set forth in claim 1, wherein
when forming a conductive pattern on the treated substrate body, a first conductive pattern is formed on the first principal surface and a second conductive pattern is formed on a second principal surface.

12. An electronic component comprising:
a substrate; and
a conductive pattern formed on the substrate,
wherein the electronic component is manufactured such that:
preparing a worked substrate;
forming a lattice-shaped resist film on the worked substrate;
performing wet-etching on the worked substrate so as to make a treated substrate comprising:
a treated substrate body; and
a lattice-shaped reinforcing part standing on a first principal surface of the treated substrate body;
forming the conductive pattern on the treated substrate body; and
cutting the treated substrate body so as to eliminate the reinforcing part and also divide the treated substrate body into individual electronic component, and
wherein a thickness of the substrate at an edge portion is larger than that of the substrate at a central portion.
